(19) United States
(12) Patent Application Publication
(10) Pub. No.: US 2009/0061641 A1
(43) Pub. Date: Mar. 5, 2009

(54) METHOD OF FORMING A MICRO PATTERN OF A SEMICONDUCTOR DEVICE

(75) Inventor: Woo Yung JUNG, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,857

(22) Filed: Jun. 27, 2008

(30) Foreign Application Priority Data
Sep. 3, 2007 (KR) 2007-88888

(51) Int. Cl. H01L 21/308

(52) U.S. Cl. 438/740; 257/E21.039; 257/E21.236; 257/E21.234

(57) ABSTRACT

In a method of forming micro patterns, an etch target layer, a hard mask layer, a silicon-containing bottom anti-reflective coating (BARC) layer, and first auxiliary patterns are formed over a semiconductor substrate. The silicon-containing BARC layer is etched to form silicon-containing BARC patterns. Insulating layers are formed on a surface of the silicon-containing BARC patterns and the first auxiliary patterns. A second auxiliary layer is formed on the hard mask layer and the insulating layers. An etch process is performed such that the second auxiliary layer remains on the hard mask layer between the silicon-containing BARC patterns thereby forming second auxiliary patterns. The insulating layers on the first auxiliary patterns and between the silicon-containing BARC patterns and the second auxiliary patterns are removed. The hard mask layer is etched thereby forming hard mask patterns. The etch target layer is etched using the hard mask patterns as an etch mask.

### CROSS-REFERENCES TO RELATED APPLICATION

The present application claims priority to Korean patent application number 10-2007-088888, filed on Sep. 3, 2007, which is incorporated by reference in its entirety.

### BACKGROUND OF THE INVENTION

The present invention relates to a method of forming micro patterns of a semiconductor device and, more particularly, to a method of forming micro patterns of a semiconductor device, which can form more micro patterns than the resolution of an exposure apparatus.

A minimum line width implemented with highly integrated devices is becoming increasingly smaller. However, an exposure apparatus for implementing a micro line width is limited by its inherent resolution. In particular, silicon (Si)-containing photoresist patterns are formed by performing exposure and development processes on a silicon-containing photoresist layer using an exposure apparatus. Accordingly, it becomes difficult to apply the silicon-containing photoresist layer in the exposure and development processes due to the limited resolution of the silicon-containing photoresist layer.

### BRIEF SUMMARY OF THE INVENTION

The present invention is directed towards a method of forming micro patterns of a semiconductor device, which can form more micro patterns than the resolution of an exposure apparatus.

According to a method of forming micro patterns of a semiconductor device in accordance with an aspect of the present invention, an etch target layer, a hard mask layer, a silicon-containing bottom anti-reflective coating (BARC) layer, and first auxiliary patterns are formed over a semiconductor substrate. The silicon-containing BARC layer is etched using the first auxiliary patterns as an etch mask thereby forming silicon-containing BARC patterns. Insulating layers are formed on a surface of the silicon-containing BARC patterns and the first auxiliary patterns. A second auxiliary layer is formed on the hard mask layer and the insulating layers. An etch process is performed such that the second auxiliary layer remains on the hard mask layer between the silicon-containing BARC patterns to form second auxiliary patterns. The insulating layers on the first auxiliary patterns and between the silicon-containing BARC patterns and the second auxiliary patterns are removed. The hard mask layer is etched using the silicon-containing BARC patterns and the second auxiliary patterns as an etch mask, thereby forming hard mask patterns. The etch target layer is etched using the hard mask patterns as an etch mask.

The etch target layer may be comprised of a film of insulating material or conductive material. The hard mask layer may have a stacked structure of an amorphous carbon layer and a silicon oxynitride (SiON) layer. The first auxiliary patterns may be formed from a photoresist layer. The critical dimension (CD) of the first auxiliary patterns may be about half a pitch of micro patterns formed by a final process.

The insulating layers may be formed from an organic layer or an amorphous carbon layer. In the formation process of the insulating layers, the insulating layers may be formed on the hard mask layer. The insulating layers may be formed from material having an etch selectivity that is different from the silicon-containing BARC patterns and the second auxiliary layer. The insulating layers may have the same etch selectivity as the first auxiliary patterns. The thickness of the insulating layers deposited on sides of the silicon-containing BARC patterns and the first auxiliary patterns may be about half a pitch of micro patterns formed by a final process.

The second auxiliary layer may be etched using an etchback process. During the etch process of the second auxiliary layer, the second auxiliary patterns remain at the same height as the first auxiliary patterns. The insulating layers may be removed by a dry etch process. The insulating layers may have an etch selectivity that is different from the silicon-containing BARC patterns and the second auxiliary patterns.

The insulating layers formed on the hard mask layer may remain below the second auxiliary patterns when the insulating layers are removed. When the insulating layers are removed, the first auxiliary patterns may also be removed. The second auxiliary patterns may be formed between the silicon-containing BARC patterns.

According to a method of forming micro patterns of a semiconductor device in accordance with an aspect of the present invention, an etch target layer, a hard mask layer, a silicon-containing BARC layer, and first auxiliary patterns are formed over a semiconductor substrate. A cell gate area, a select transistor area, and a peri area are defined in the semiconductor substrate. The silicon-containing BARC layer is etched using the first auxiliary patterns as an etch mask thereby forming silicon-containing BARC patterns. Insulating layers are formed on surfaces of the silicon-containing BARC patterns and the first auxiliary patterns. A second auxiliary layer is formed on the hard mask layer and the insulating layers. The second auxiliary layer formed in the select transistor area and the peri area is removed. An etch process is performed such that the second auxiliary layer formed in the cell gate area remains on the hard mask layer between the silicon-containing BARC patterns to form second auxiliary patterns. The insulating layers on the first auxiliary patterns and between the silicon-containing BARC patterns and the second auxiliary patterns in the cell gate area are removed. The hard mask layer is etched using the silicon-containing BARC patterns and the second auxiliary patterns as an etch mask thereby forming hard mask patterns. The etch target layer is etched using the hard mask patterns as an etch mask.

The etch target layer may be formed from a tungsten silicide (WSix) layer. A stacked structure of a tunnel insulating layer, a first conductive layer for a floating gate, a dielectric layer, and a second conductive layer for a control gate may be formed between the etch target layer and the semiconductor substrate. The hard mask layer may have a stacked structure of an amorphous carbon layer and a silicon oxynitride (SiON) layer.

The first auxiliary patterns may be formed from a photoresist layer. The CD of the first auxiliary patterns may be about half a pitch of micro patterns formed by a final process. The insulating layers may be formed from material having an etch selectivity that is different from that of the second auxiliary layer and the silicon-containing BARC patterns. The insulating layers may be formed from an organic layer or an amorphous carbon layer. The insulating layers may be formed on the hard mask layer. The insulating layers may have the same etch selectivity as that of the first auxiliary patterns.

The thickness of the insulating layers deposited on sides of the silicon-containing BARC patterns may be about half a pitch of micro patterns formed by a final process. The second auxiliary layer may be formed from a silicon-containing photoresist layer. The second auxiliary layer formed in the select transistor area and the peri area may be removed using a dry etch process. During the etch process of the second auxiliary layer formed in the cell gate area, the second auxiliary layer remaining in the select transistor area may be removed.

The second auxiliary layer remaining in the select transistor area may be etched using an etchback process. During the etch process of the second auxiliary layer, the second auxiliary patterns remain at the same height as the first auxiliary patterns. The insulating layers may have an etch selectivity different from the silicon-containing BARC patterns and the second auxiliary patterns. When the insulating layers formed in the cell gate area are removed, the insulating layers formed in the select transistor area and the peri area may be removed. The insulating layers formed in the select transistor area and the peri area may be removed using a dry etch process.

The insulating layers formed on the hard mask layer may remain below the second auxiliary patterns when the insulating layers are removed. The first auxiliary patterns have the same etch selectivity as the insulating layers. When the insulating layers are removed, the first auxiliary patterns may also be removed. The second auxiliary patterns may be formed between the silicon-containing BARC patterns. During the etch process of the etch target layer, the tunnel insulating layer, the first conductive layer for the floating gate, the dielectric layer, and the second conductive layer for the control gate, which may be formed between the etch target layer and the semiconductor substrate, may be etched thereby forming a gate.

### BRIEF DESCRIPTION OF THE DRAWINGS

FIGS. 1A to 1H are sectional views illustrating a method of forming micro patterns of a semiconductor device in accordance with a first embodiment of the present invention; and

FIGS. 2A to 2I are sectional views illustrating a method of forming micro patterns of a semiconductor device in accordance with a second embodiment of the present invention.

### DESCRIPTION OF SPECIFIC EMBODIMENTS

Specific embodiments according to the present invention will be described with reference to the accompanying drawings. However, the present invention is not limited to the disclosed embodiments, but may be implemented in various manners. The embodiments are provided to complete the disclosure of the present invention and to allow those having ordinary skill in the art to understand the present invention. The present invention is defined by the scope of the claims.

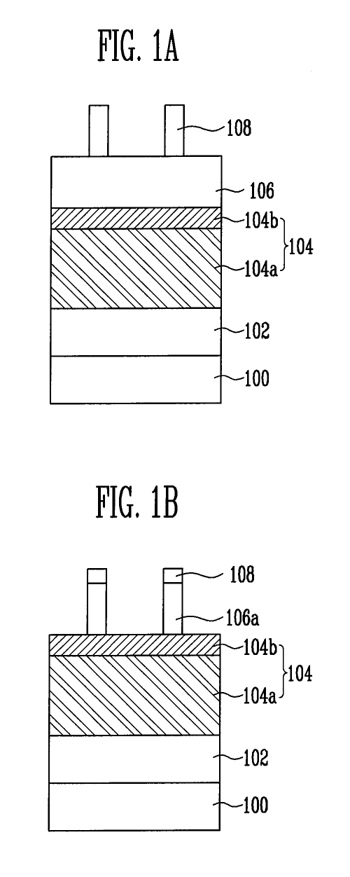

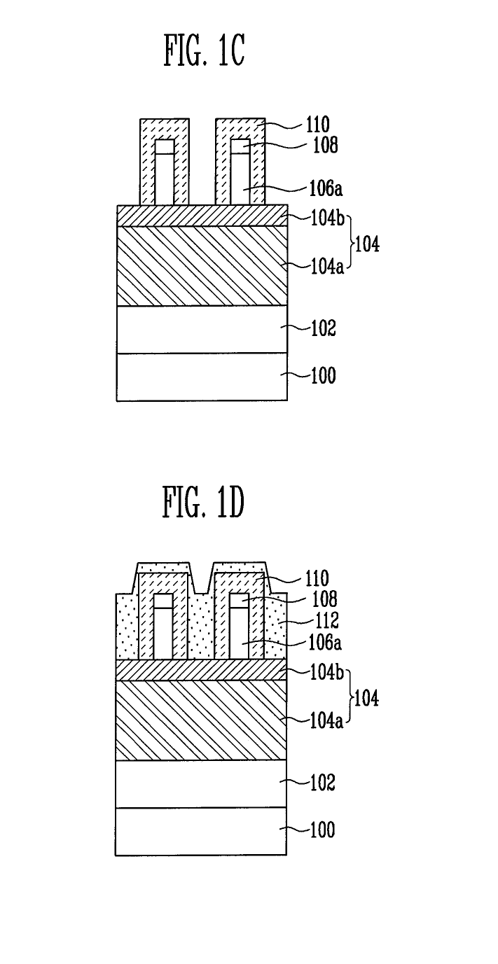

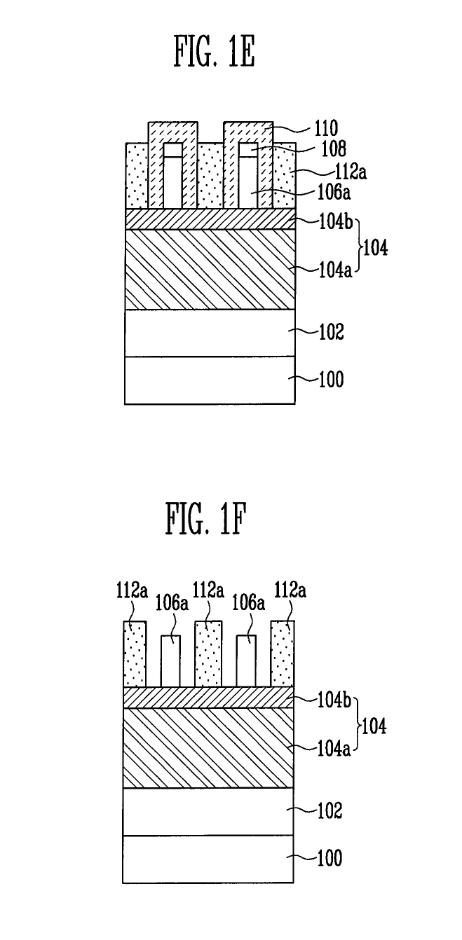

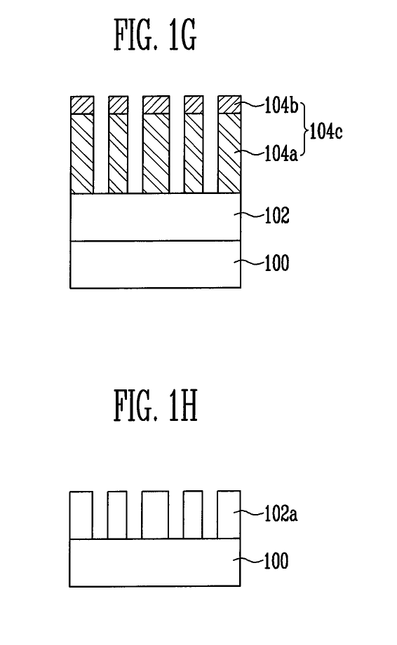

FIGS. 1A to 1H are sectional views illustrating a method of forming micro patterns of a semiconductor device in accordance with a first embodiment of the present invention. Process steps are performed on a cell gate area of a semiconductor substrate.

Referring to FIG. 1A, an etch target layer 102 is formed over a semiconductor substrate 100. The etch target layer 102 may be a film of insulating material, conductive material or the like. A hard mask layer 104 and a silicon-containing bottom anti-reflective coating (BARC) 106 are formed over the etch target layer 102. The hard mask layer 104 may have a stacked structure of an amorphous carbon layer 104a and a silicon oxynitride (SiON) layer 104b.

First auxiliary patterns 108 are formed on the silicon-containing BARC layer 106. The first auxiliary patterns 108 may be formed from a photoresist layer. When the first auxiliary patterns 108 are formed using a general photoresist layer, more micro patterns than the resolution of an exposure apparatus may be formed rather than by using a silicon-containing photoresist layer. The critical dimension (CD) of the first auxiliary patterns 108 is about half the pitch of micro patterns formed by a final process.

Referring to FIG. 1B, the silicon-containing BARC layer 106 is etched using the first auxiliary patterns 108 as an etch mask thereby forming silicon-containing BARC patterns 106a. During the etch process of the silicon-containing BARC layer, the first auxiliary patterns 108 are partially removed. Thus, patterns are formed in which the silicon-containing BARC patterns 106a and the first auxiliary patterns 108 are stacked.

Referring to FIG. 1C, insulating layers 110 are formed on surfaces of the silicon-containing BARC patterns 106a and the first auxiliary patterns 108. The insulating layers 110 may be formed from an organic layer or an amorphous carbon layer. During the formation process of the insulating layers 110, the insulating layers 110 may be formed on the surfaces of the silicon-containing BARC patterns 106a and the first auxiliary patterns 108, and a portion of a top surface of the hard mask layer 104. The insulating layers 110 are formed from material having a different etch selectivity with respect to the material of a second auxiliary layer 112, which will be formed in a subsequent process, and the silicon-containing BARC patterns 106a. Accordingly, during a subsequent process for removing the insulating layers 110, the silicon-containing BARC patterns 106a and the second auxiliary patterns 112a may be removed without being damaged. The thickness of each insulating layer 110, deposited on the sides of the silicon-containing BARC patterns 106a and the first auxiliary patterns 108, is about half the pitch of micro patterns formed in a final process.

Referring to FIG. 1D, a second auxiliary layer 112 is formed on the hard mask layer 104 and the insulating layers 110 such that a space between the patterns having the stacked structure of the silicon-containing BARC patterns 106a and the first auxiliary patterns 108 is gap-filled. The second auxiliary layer 112 may be formed from a silicon-containing photoresist layer. Accordingly, the second auxiliary layer 112 has an etch selectivity that is different from the insulating layers 110.

Referring to FIG. 1E, the second auxiliary layer 112 is etched until a top surface of the insulating layers 110 is exposed, thereby forming second auxiliary patterns 112a. The etch process may be performed using an etchback process. In the etch process of the second auxiliary layer 112, the second auxiliary layer 112 formed between the insulating layers 110 remains at the same height as the first auxiliary patterns 108. The second auxiliary layer 112 has a different etch selectivity with respect to the insulating layers 110. Thus, the silicon-containing BARC patterns 106a and the second auxiliary patterns 112a have the same etch selectivity.

Referring to FIG. 1F, the insulating layers 110 exposed by the etch process of the second auxiliary layer 112, and the insulating layers 110 formed between the silicon-containing BARC patterns 106a and the second auxiliary patterns 112a are removed. The insulating layers 110 may be removed using a dry etch process. When the insulating layers 110 are removed, the first auxiliary patterns 108 are also removed. As described above with reference to FIG. 1C, if the insulating layers 110 are formed on the hard mask layer 104, the insulating layers 110 remain below the second auxiliary patterns 112a when the insulating layers 110 are removed.

The insulating layers 110 have a different etch selectivity with respect to the materials of the silicon-containing BARC patterns 106a and the second auxiliary patterns 112a, but have the same etch selectivity as the first auxiliary patterns 108. As described above, by forming the second auxiliary patterns 112a between the silicon-containing BARC patterns 106a, the silicon-containing BARC patterns 106a may be formed to have a desired pitch.

Referring to FIG. 1G, the hard mask layer 104 is etched using the silicon-containing BARC patterns 106a and the second auxiliary patterns 112a as an etch mask thereby forming hard mask patterns 104c having a desired line and space. The hard mask layer 104 is removed using a dry etch process. By forming the silicon-containing BARC patterns 106a and the second auxiliary patterns 112a to have the same etch selectivity, the etch process may be easily performed on the hard mask layer 104. Thus, the hard mask patterns 104c may be formed uniformly. In other words, an etch process is easier to perform when etching the hard mask layer 104 using the silicon-containing BARC patterns 106a and the second auxiliary patterns 112a having the same etch selectivity than by etching the hard mask layer 104 using the silicon-containing BARC patterns 106a and the second auxiliary patterns 112a having a different etch selectivity.

The silicon-containing BARC patterns 106a and the second auxiliary patterns 112a are removed to form micro patterns comprised of the hard mask patterns 104c.

Referring to FIG. 1H, the etch target layer 102 is etched using the hard mask patterns 104c having a desired line and space as an etch mask thereby forming target patterns 102a. The hard mask patterns 104c are then removed.

As described above, when the silicon-containing BARC patterns 106a are formed as the first auxiliary patterns 108 using a general photoresist layer, more micro patterns may be formed than the resolution of an existing exposure apparatus.

The above method may be applied to a method of fabricating a NAND flash memory device as follows.

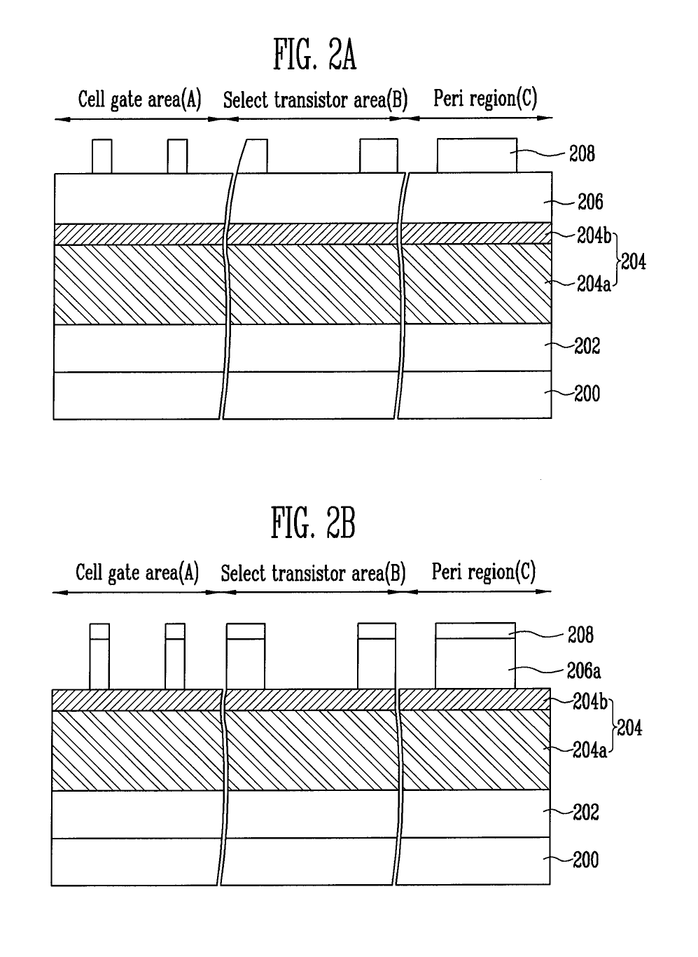

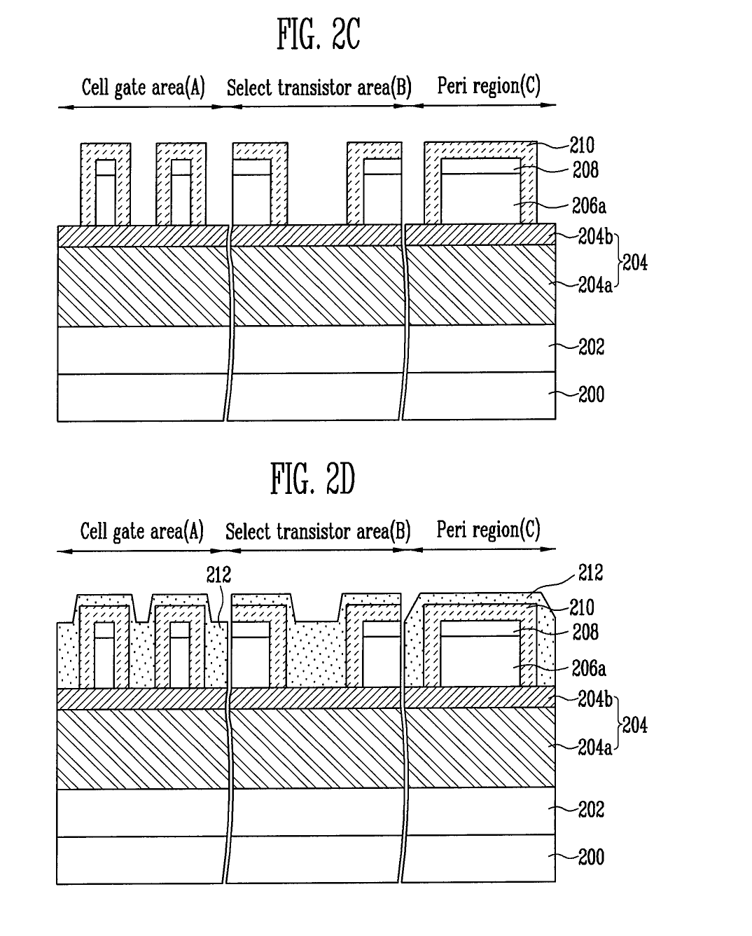

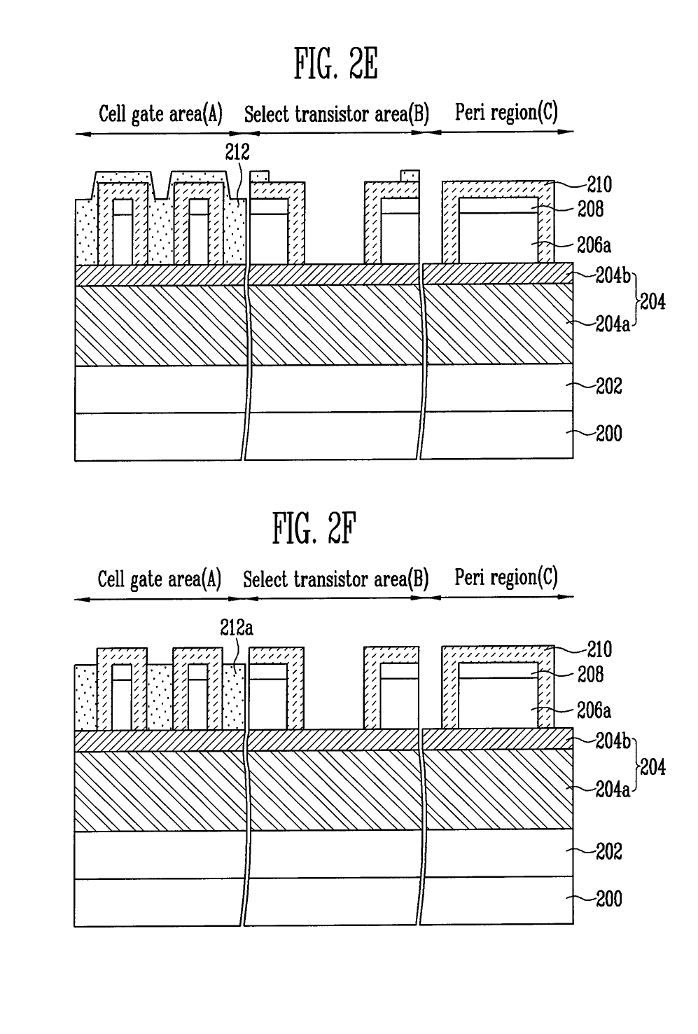

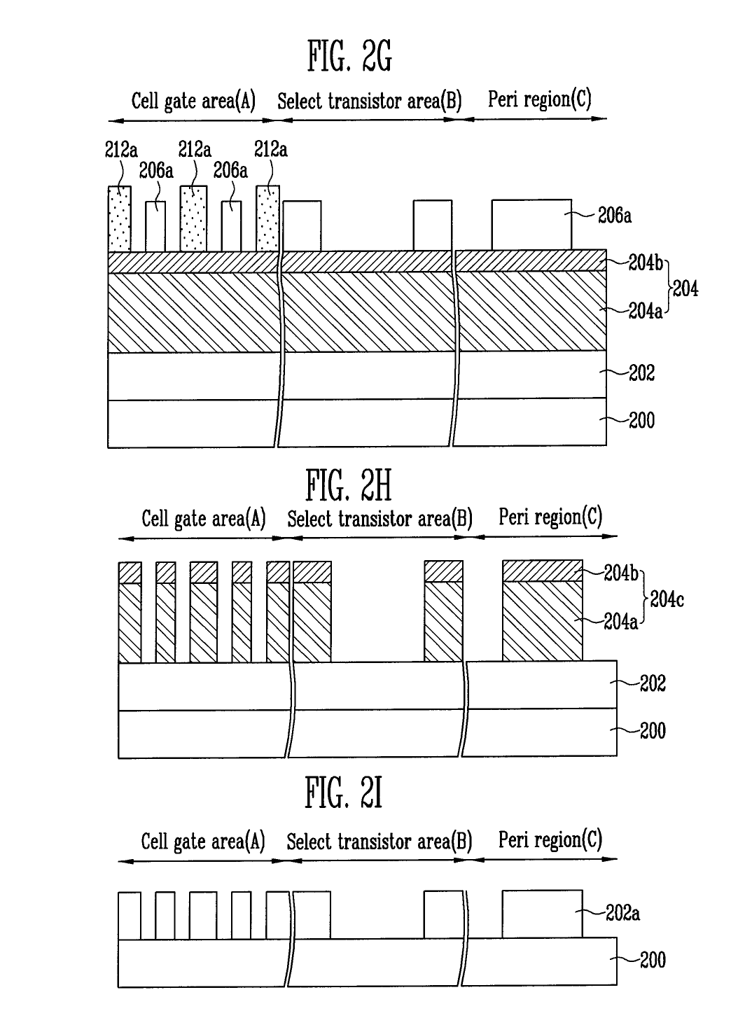

FIGS. 2A to 2I are sectional views illustrating a method of forming micro patterns of a semiconductor device in accordance with a second embodiment of the present invention.

Referring to FIG. 2A, an etch target layer 202 is formed over a semiconductor substrate 200 in which a cell gate area A, a select transistor area B and a peri area C are defined. The etch target layer 202 may be formed from a tungsten silicide (WSix) layer. A stacked structure of a tunnel insulating layer, a first conductive layer for a floating gate, a dielectric layer and a second conductive layer for a control gate is formed between the tungsten silicide (WSix) layer and the semiconductor substrate 200.

A hard mask layer 204 and a silicon-containing BARC layer 206 are formed over the etch target layer 202. The hard mask layer 204 may have a stacked structure of an amorphous carbon layer 204a and a silicon oxynitride (SiON) layer 204b.

First auxiliary patterns 208 are formed on the silicon-containing BARC layer 206. The first auxiliary patterns 208 may be formed from a photoresist layer. When the first auxiliary patterns 208 are formed using a general photoresist layer, more micro patterns than the resolution of an exposure apparatus may be formed rather than by using a silicon-containing photoresist layer. The CD of the first auxiliary patterns 208 is about half the pitch of micro patterns formed by a final process.

Referring to FIG. 2B, the silicon-containing BARC layer 206 is etched using the first auxiliary patterns 208 as an etch mask thereby forming silicon-containing BARC patterns 206a. During the etch process of the silicon-containing BARC layer, the first auxiliary patterns 208 are partially removed. Thus, patterns are formed in which the silicon-containing BARC patterns 206a and the first auxiliary patterns 208 are stacked.

Referring to FIG. 2C, insulating layers 210 are formed on surfaces of the silicon-containing BARC patterns 206a and the first auxiliary patterns 208. The insulating layers 210 can be formed from an organic layer or an amorphous carbon layer. During the formation process of the insulating layers 210, the insulating layers 210 may be formed on the surfaces of the silicon-containing BARC patterns 206a and the first auxiliary patterns 208, and on a portion of a top surface of the hard mask layer 204. The insulating layers 210 are formed from material having a different etch selectivity with respect to the materials of a second auxiliary layer 212, which will be formed in a subsequent process, and the silicon-containing BARC patterns 206a. Accordingly, during a subsequent process for removing the insulating layers 210, the silicon-containing BARC patterns 206a and the second auxiliary patterns 212a may be removed without being damaged. The thickness of each insulating layer 210, deposited on the sides of the silicon-containing BARC patterns 206a and the first auxiliary patterns 208, is about half the pitch of micro patterns formed in a final process.

Referring to FIG. 2D, a second auxiliary layer 212 is formed on the hard mask layer 204 and the insulating layers 210 such that a space between the patterns having the stacked structure of the silicon-containing BARC patterns 206a and the first auxiliary patterns 208 is gap-filled. The second auxiliary layer 212 may be formed from a silicon-containing photoresist layer. Accordingly, the second auxiliary layer 212 has an etch selectivity that is different from the insulating layers 210.

Referring to FIG. 2E, photoresist patterns (not shown) are formed on the second auxiliary layer 212 of the cell gate area A such that the select transistor area B and the peri area C are exposed. The second auxiliary layer 212 formed in the select transistor area B and the peri area C is removed because micro patterns are not necessary in the select transistor area B and the peri area C.

The second auxiliary layer 212 formed in the select transistor area B and the peri area C is removed using the photoresist patterns as an etch mask. Thereafter, the photoresist patterns are removed.

Referring to FIG. 2F, the second auxiliary layer 212 formed in the cell gate area A is etched until a top surface of the insulating layers 210 is exposed thereby forming second auxiliary patterns 212a in the cell gate area A. The etch process may be performed using an etchback process. The second auxiliary layer 212 formed between the insulating layers 210 remains at the same height as the first auxiliary patterns 208. The second auxiliary layer 212 formed in the select transistor area B is removed until a top surface of the insulating layers 210 is exposed. The second auxiliary layer 212 has a different etch selectivity with respect to the insulating layers 210. Thus, the silicon-containing BARC patterns 206a and the second auxiliary patterns 212a have the same etch selectivity.

Referring to FIG. 2G, the insulating layers 210 exposed by the etch process of the second auxiliary layer 212, and the insulating layers 210 formed between the silicon-containing BARC patterns 206a and the second auxiliary patterns 212a are removed. The insulating layers 210 may be removed using a dry etch process. As described above with reference to FIG. 2C, if the insulating layers 210 are formed on the hard mask layer 204, the insulating layers 210 remain below the second auxiliary patterns 212a when the insulating layers 210 are removed. Thus, when the insulating layers 210 are removed, the first auxiliary patterns 208 are also removed.

The insulating layers 210 have a different etch selectivity with respect to the materials of the silicon-containing BARC patterns 206a and the second auxiliary patterns 212a, but have the same etch selectivity as the first auxiliary patterns 208. As described above, by forming the second auxiliary patterns 212a between the silicon-containing BARC patterns 206a, the silicon-containing BARC patterns 206a may be formed to have a desired pitch. When the insulating layers 210 formed in the cell gate area A are removed, the insulating layers 210 formed in the select transistor area B and the peri area C are also removed.

Referring to FIG. 2H, the hard mask layer 204 is etched using the silicon-containing BARC patterns 206a and the second auxiliary patterns 212a as an etch mask thereby forming hard mask patterns 204c having a desired line and space. The hard mask layer 204 is removed using a dry etch process. By forming the silicon-containing BARC patterns 206a and the second auxiliary patterns 212a to have the same etch selectivity, the etch process may be easily performed on the hard mask layer 204. Thus, the hard mask patterns 204c may be formed uniformly. In other words, an etch process is easier to perform when etching the hard mask layer 204 using the silicon-containing BARC patterns 206a and the second auxiliary patterns 212a having the same etch selectivity than by etching the hard mask layer 204 using the silicon-containing BARC patterns 206a and the second auxiliary patterns 212a having a different etch selectivity.

The silicon-containing BARC patterns 206a and the second auxiliary patterns 212a are removed to form micro patterns comprised of the hard mask patterns 204c.

Referring to FIG. 2I, the etch target layer 202 is etched using the hard mask patterns 204c having a desired line and space as an etch mask thereby forming target patterns 202a. The hard mask patterns 204c are then removed.

During the etch process of the etch target layer 202, the tunnel insulating layer, the first conductive layer for the floating gate, the dielectric layer, and the second conductive layer for the control gate, which are formed between the etch target layer 202 and the semiconductor substrate 200, are also etched to form a gate. The hard mask patterns 204c are then removed.

As described above, when the silicon-containing BARC patterns 206a are formed as the first auxiliary patterns 208 using a general photoresist layer, more micro patterns than the resolution of an existing exposure apparatus may be formed.

As described above, the present invention has the following advantages.

First, by forming the silicon-containing BARC patterns, as the first auxiliary patterns, using a general photoresist layer, more micro patterns than the resolution of an existing exposure apparatus may be formed.

Second, an existing double exposure etch tech (DEET) method or an existing spacer formation process, which are used to form micro patterns, is not required. Accordingly, the number of process steps may be reduced.

Third, since the number of process steps is reduced, the cost of mass producing devices may be reduced.

The embodiments disclosed herein have been proposed to allow a person skilled in the art to easily implement the present invention, and the person skilled in the part may implement the present invention by a combination of these embodiments. Therefore, the scope of the present invention is not limited by or to the embodiments as described above, and should be construed to be defined only by the appended claims and their equivalents.

What is claimed is:

1. A method of forming micro patterns of a semiconductor device, the method comprising:
forming an etch target layer, a hard mask layer, a silicon-containing bottom anti-reflective coating (BARC) layer, and first auxiliary patterns over a semiconductor substrate;
etching the silicon-containing BARC layer using the first auxiliary patterns as an etch mask thereby forming silicon-containing BARC patterns;
forming insulating layers over the silicon-containing BARC patterns and the first auxiliary patterns;
forming a second auxiliary layer over the hard mask layer and the insulating layers;
performing an etch process such that the second auxiliary layer remains on the hard mask layer between the silicon-containing BARC patterns thereby forming second auxiliary patterns;
removing the insulating layers on the first auxiliary patterns and between the silicon-containing BARC patterns and the second auxiliary patterns;
etching the hard mask layer using the silicon-containing BARC patterns and the second auxiliary patterns as an etch mask thereby forming hard mask patterns; and
etching the etch target layer using the hard mask patterns as an etch mask.

2. The method of claim 1, wherein the etch target layer comprises a film of insulating material or conductive material.

3. The method of claim 1, wherein the hard mask layer has a stacked structure of an amorphous carbon layer and a silicon oxynitride (SiON) layer.

4. The method of claim 1, wherein the first auxiliary patterns comprise a photoresist layer.

5. The method of claim 1, wherein a critical dimension (CD) of the first auxiliary patterns is about half a pitch of micro patterns formed by a final process.

6. The method of claim 1, wherein the insulating layers comprise an organic layer or an amorphous carbon layer.

7. The method of claim 1, wherein in the formation process of the insulating layers, the insulating layers are formed over the hard mask layer.

8. The method of claim 1, wherein the insulating layers are formed from material having an etch selectivity that is different from an etch selectivity of the silicon-containing BARC patterns and the second auxiliary layer.

9. The method of claim 1, wherein the insulating layers have the same etch selectivity as the first auxiliary patterns.

10. The method of claim 1, wherein a thickness of the insulating layers deposited on sides of the silicon-containing BARC patterns and the first auxiliary patterns is about half a pitch of micro patterns formed by a final process.

11. The method of claim 1, wherein the second auxiliary layer is etched using an etchback process.

12. The method of claim 1, wherein during the etch process of the second auxiliary layer, the second auxiliary patterns have the same height as the first auxiliary patterns.

13. The method of claim 1, wherein the insulating layers are removed by a dry etch process.

14. The method of claim 1, wherein the insulating layers have an etch selectivity that is different from the silicon-containing BARC patterns and the second auxiliary patterns.

15. The method of claim 7, wherein the insulating layers formed on the hard mask layer remain below the second auxiliary patterns when the insulating layers are removed.

16. The method of claim 1, wherein when the insulating layers are removed, the first auxiliary patterns are removed.

17. The method of claim 1, wherein the second auxiliary patterns are formed between the silicon-containing BARC patterns.

18. A method of forming micro patterns of a semiconductor device, the method comprising:
forming an etch target layer, a hard mask layer, a silicon-containing BARC layer, and first auxiliary patterns over a semiconductor substrate, wherein a cell gate area, a select transistor area, and a peri area are defined in the semiconductor substrate;
etching the silicon-containing BARC layer using the first auxiliary patterns as an etch mask thereby forming silicon-containing BARC patterns;
forming insulating layers over a surface of the silicon-containing BARC patterns and the first auxiliary patterns;
forming a second auxiliary layer over the hard mask layer and the insulating layers;
removing the second auxiliary layer formed in the select transistor area and the peri area;
performing an etch process such that the second auxiliary layer formed in the cell gate area remains on the hard mask layer between the silicon-containing BARC patterns thereby forming second auxiliary patterns;
in the cell gate area, removing the insulating layers on the first auxiliary patterns and between the silicon-containing BARC patterns and the second auxiliary patterns;
etching the hard mask layer using the silicon-containing BARC patterns and the second auxiliary patterns as an etch mask thereby forming hard mask patterns; and
etching the etch target layer using the hard mask patterns as an etch mask.

19. The method of claim 18, wherein the etch target layer comprises a tungsten silicide (WSix) layer.

20. The method of claim 18, wherein a stacked structure of a tunnel insulating layer, a first conductive layer for a floating gate, a dielectric layer, and a second conductive layer for a control gate is formed between the etch target layer and the semiconductor substrate.

21. The method of claim 18, wherein the hard mask layer has a stacked structure of an amorphous carbon layer and a silicon oxynitride (SiON) layer.

22. The method of claim 18, wherein the first auxiliary patterns comprise a photoresist layer.

23. The method of claim 18, wherein a CD of the first auxiliary patterns is about half a pitch of micro patterns formed by a final process.

24. The method of claim 18, wherein the insulating layers are formed from material having an etch selectivity that is different from the second auxiliary layer and the silicon-containing BARC patterns.

25. The method of claim 18, wherein the insulating layers are formed from an organic layer or an amorphous carbon layer.

26. The method of claim 18, wherein in the formation process of the insulating layers, the insulating layers are formed on the hard mask layer.

27. The method of claim 18, wherein the insulating layers have the same etch selectivity as the first auxiliary patterns.

28. The method of claim 18, wherein a thickness of the insulating layers deposited on sides of the silicon-containing BARC patterns is about half a pitch of micro patterns formed by a final process.

29. The method of claim 18, wherein the second auxiliary layer comprises a silicon-containing photoresist layer.

30. The method of claim 18, wherein the second auxiliary layer formed in the select transistor area and the peri area is removed using a dry etch process.

31. The method of claim 18, wherein during the etch process of the second auxiliary layer formed in the cell gate area, the second auxiliary layer remaining in the select transistor area is removed.

32. The method of claim 31, wherein the second auxiliary layer remaining in the select transistor area is etched using an etchback process.

33. The method of claim 18, wherein during the etch process of the second auxiliary layer, the second auxiliary patterns have the same height as the first auxiliary patterns.

34. The method of claim 18, wherein the insulating layers have an etch selectivity that is different from the silicon-containing BARC patterns and the second auxiliary patterns.

35. The method of claim 18, wherein when the insulating layers formed in the cell gate area are removed, the insulating layers formed in the select transistor area and the peri area are removed.

36. The method of claim 35, wherein the insulating layers formed in the select transistor area and the peri area are removed using a dry etch process.

37. The method of claim 26, wherein the insulating layers formed on the hard mask layer remain below the second auxiliary patterns when the insulating layers are removed.

38. The method of claim 18, wherein the first auxiliary patterns have the same etch selectivity as the insulating layers.

39. The method of claim 18, wherein when the insulating layers are removed, the first auxiliary patterns are removed.

40. The method of claim 18, wherein the second auxiliary patterns are formed between the silicon-containing BARC patterns.

41. The method of claim 40, wherein during the etch process of the etch target layer, the tunnel insulating layer, the first conductive layer for the floating gate, the dielectric layer, and the second conductive layer for the control gate are etched thereby forming a gate, wherein the tunnel insulating layer, the first conductive layer for the floating gate, the dielectric layer, and the second conductive layer for the control gate are formed between the etch target layer and the semiconductor substrate.
